(19) United States
(12) Patent Application Publication
(10) Pub. No.: US 2013/0186945 A1
(43) Pub. Date: Jul. 25, 2013

(54) MANUFACTURING METHOD FOR ELECTRONIC DEVICE AND ELECTRONIC DEVICE MANUFACTURING APPARATUS

(71) Applicant: KYOCERA CORPORATION, Kyoto-shi (JP)

(72) Inventor: Takayuki MIYAO, Kirishima-shi (JP)

(73) Assignee: KYOCERA CORPORATION, Kyoto-shi (JP)

(21) Appl. No.: 13/728,723

(22) Filed: Dec. 27, 2012

(30) Foreign Application Priority Data
Dec. 27, 2011 (JP) 2011-285783

(51) Int. Cl. H05K 13/04

(52) U.S. Cl. CPC H05K 13/04
USPC 228/221; 228/47.1

(57) ABSTRACT

An electronic device manufacturing apparatus is disclosed. The electronic device manufacturing apparatus includes a vacuum chamber, a support part, a moving part, and a heating part. The support part is located in the vacuum chamber and has a first placement surface on which a first member is to be placed. The moving part is located in the vacuum chamber and has a second placement surface on which a second member is to be placed. The moving part is movable between a first position where the first placement surface and the second placement surface do not face each other when seen in plan view and a second position where the first placement surface and the second placement surface face each other when seen in plan view. The heating part heats the first member and the second member.

### CROSS-REFERENCE TO RELATED APPLICATION

The present application claims priority under 35 U.S.C. §119 to Japanese Patent Application No. 2011-285783, filed on Dec. 27, 2011, entitled “Manufacturing Method for Electronic Device and Electronic Device Manufacturing Apparatus”. The content of which is incorporated herein by reference in its entirety.

### FIELD

The present disclosure relates to a manufacturing method for an electronic device and an electronic device manufacturing apparatus.

### BACKGROUND

In the related art, electronic devices such as a sensor device that has an electronic component such as a sensor element having a sealed space containing a small amount of gas molecules are known.

### SUMMARY

A manufacturing method for an electronic device according to one aspect of the present disclosure includes, in a vacuum, arranging a mounting structure including a wiring board and an electronic component mounted on the wiring board and a cover at positions where the mounting structure and the cover do not face each other when seen in plan view, providing a bond member on at least one of the cover and the mounting structure, heating the cover and the mounting structure to a first temperature at which the bond member melts or to a higher temperature, causing the cover and the mounting structure to face each other by moving the cover or the mounting structure, bringing the mounting structure and the cover that have been heated into contact with each other via the bond member, and bonding the mounting structure and the cover together by solidifying the bond member that has melted.

An electronic device manufacturing apparatus according to one aspect of the present disclosure includes a vacuum chamber, a support part, a moving part, and a heating part. The support part is located in the vacuum chamber and has a first placement surface on which a first member is to be placed. The moving part is located in the vacuum chamber and has a second placement surface on which a second member is to be placed. The moving part is movable between a first position where the first placement surface and the second placement surface do not face each other when seen in plan view and a second position where the first placement surface and the second placement surface face each other when seen in plan view. The heating part heats the first member and the second member.

An electronic device manufacturing apparatus according to another aspect of the present disclosure includes the vacuum chamber and a bonding device that is located in the vacuum chamber. The bonding device includes the support part, the moving part, a guide part, the heating part, and a moving mechanism. The support part has the first placement surface on which the first member is to be placed. The moving part has the second placement surface on which the second member is to be placed and is movable on the support part. The guide part is located on the moving part. The guide part is capable of moving while being fixed by the moving part and is capable of moving separately from the moving part. The heating part heats the first and second placement surfaces. The moving mechanism moves the first placement surface to a position where the first placement surface faces the second placement surface while keeping the guide part fixed on the moving part, stops the guide part at the position, and moves the moving part.

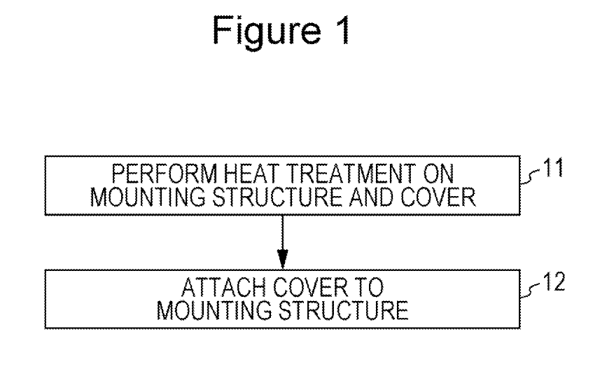

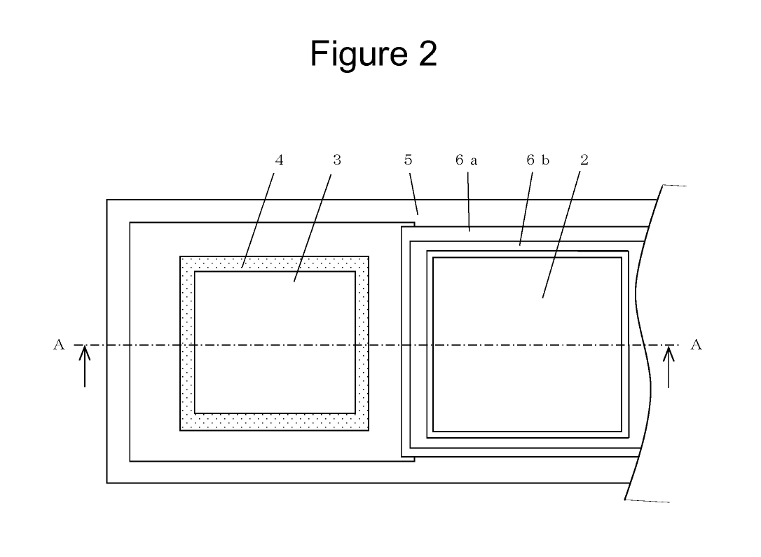

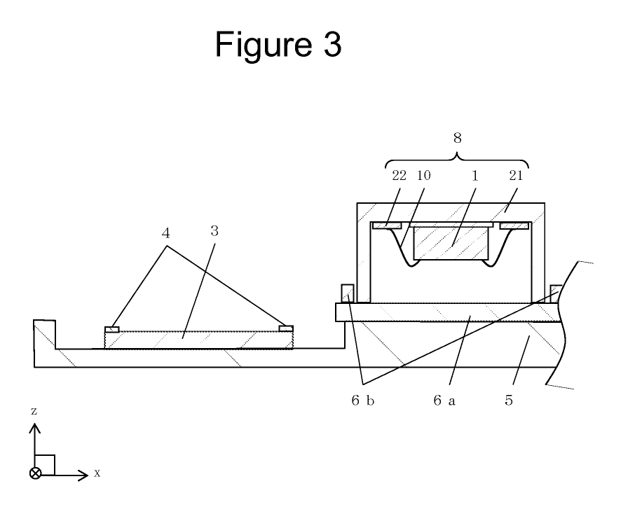

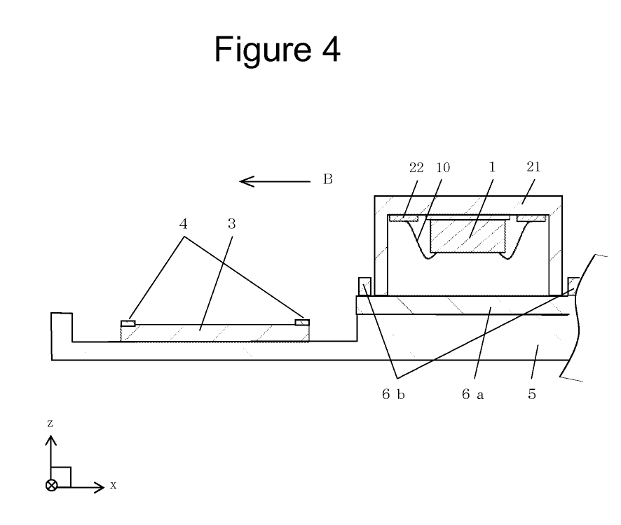

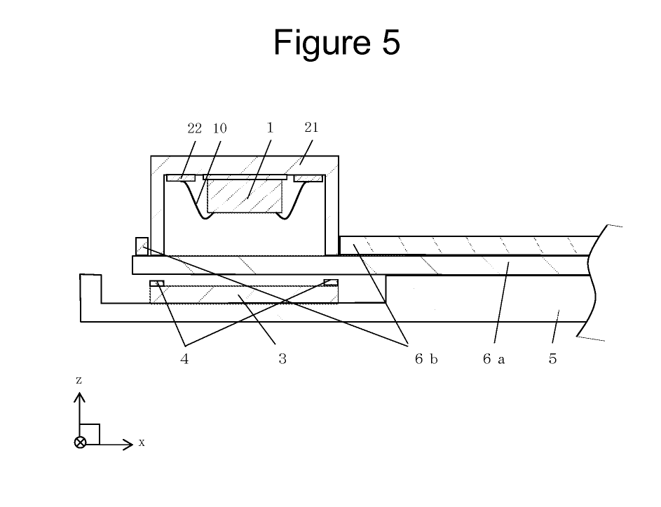

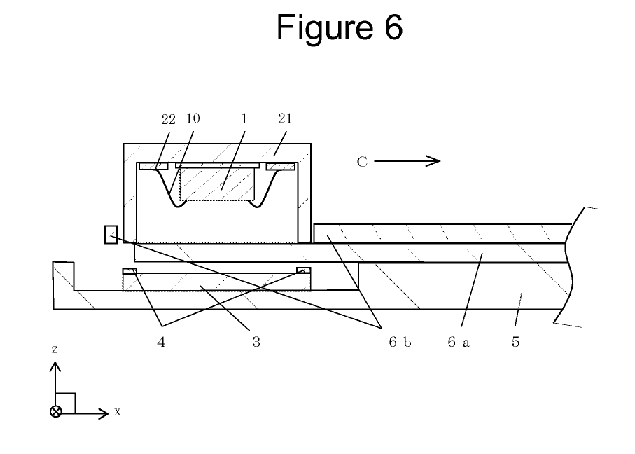

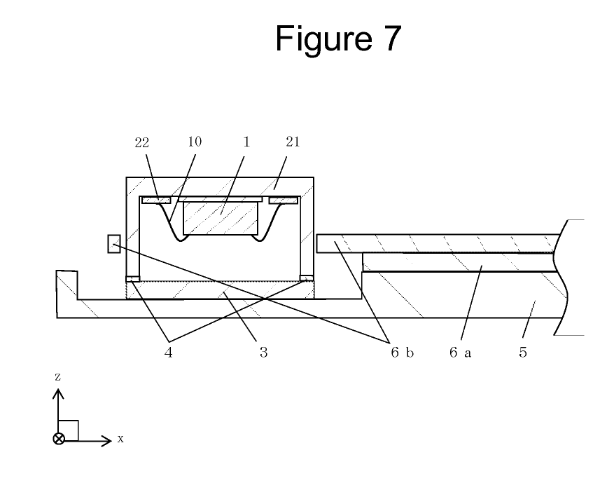

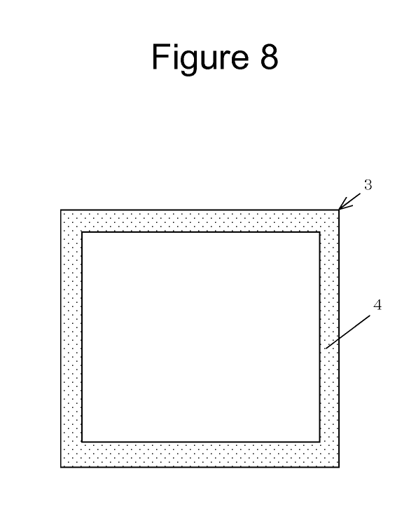

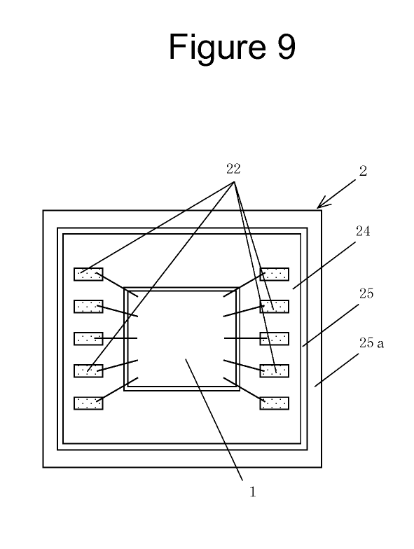

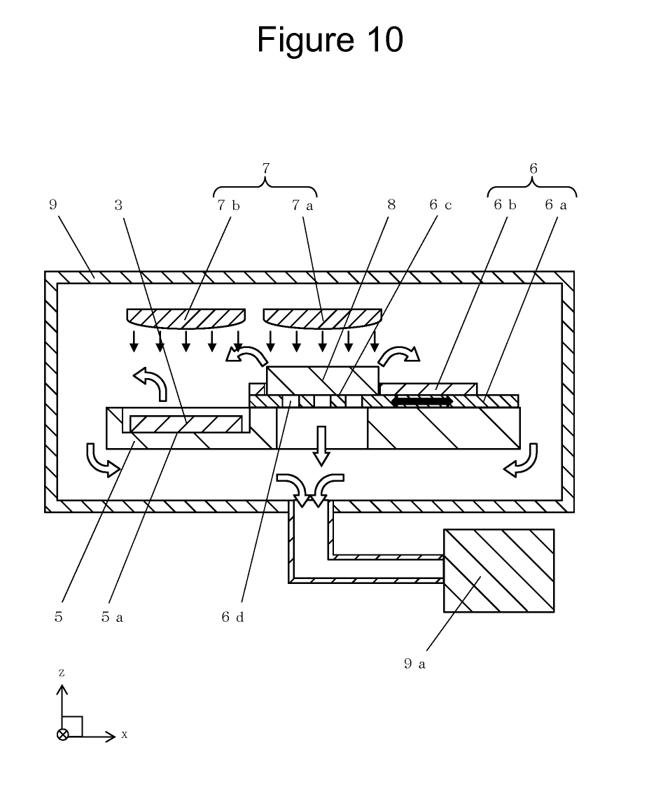

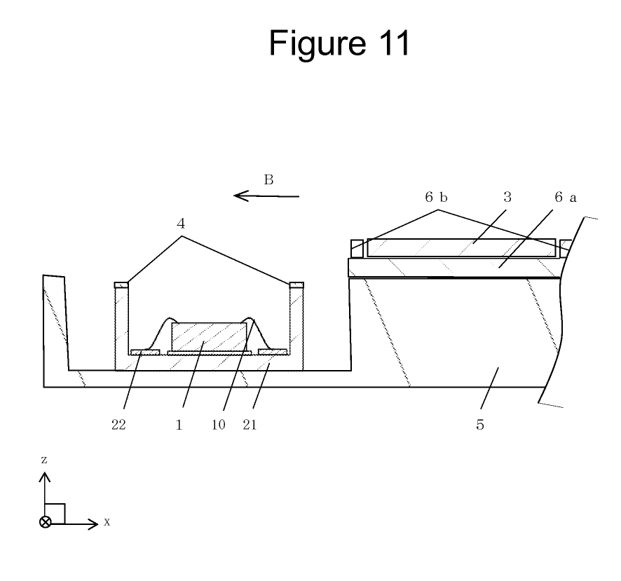

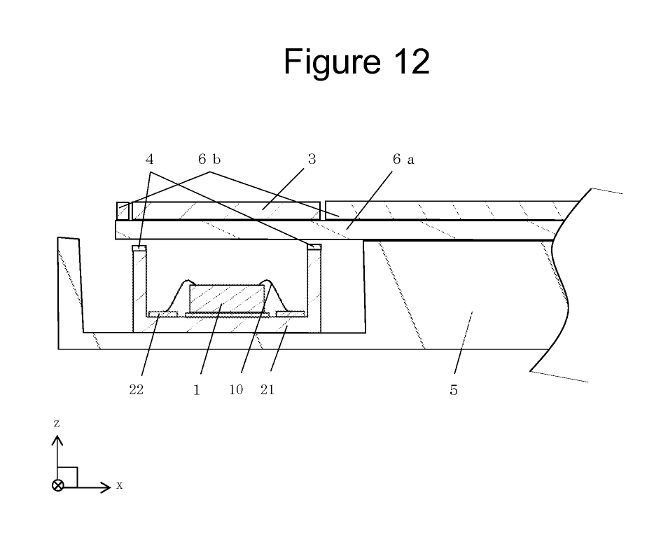

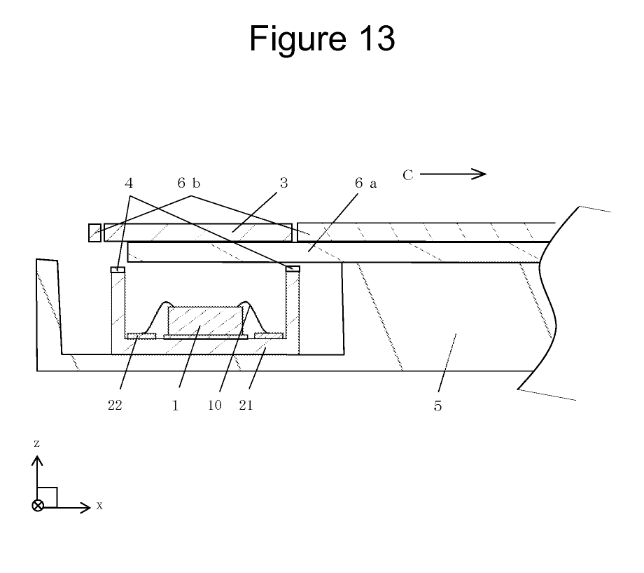

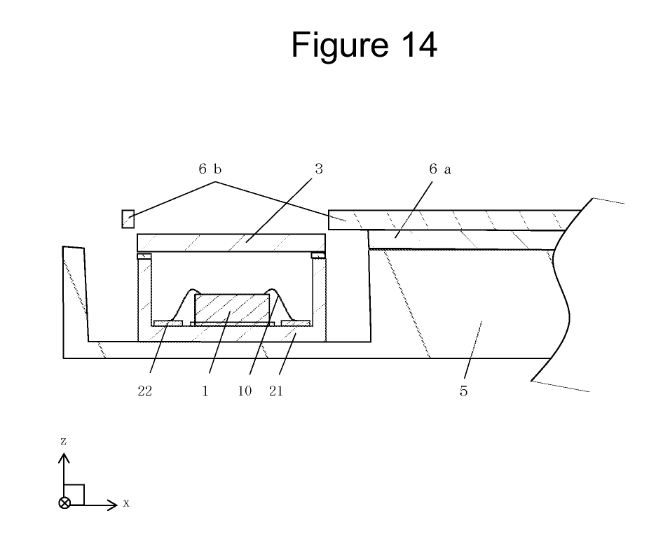

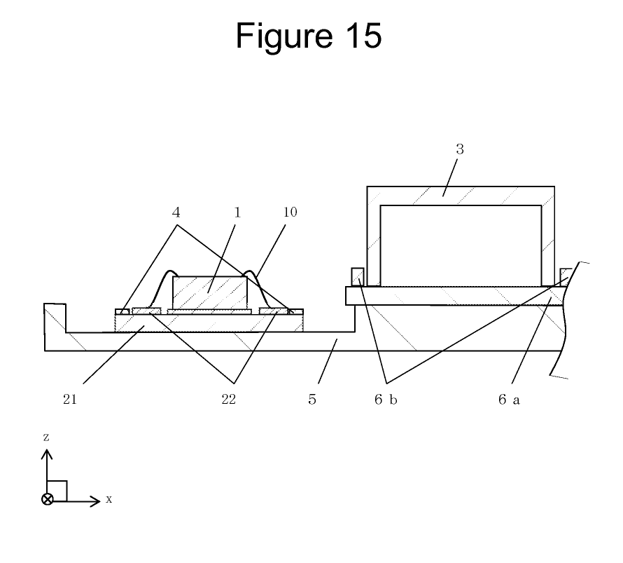

### BRIEF DESCRIPTION OF THE DRAWING

[FIG. 1] FIG. 1 shows a flowchart of a manufacturing method for an electronic device according to a first embodiment of the present disclosure.

[FIG. 2] FIG. 2 is a top view showing a step of the manufacturing method for an electronic device according to the first embodiment of the present disclosure.

[FIG. 3] FIG. 3 is a cross-sectional view taken along line A-A of FIG. 2.

[FIG. 4] FIG. 4 is a cross-sectional view showing one step of the manufacturing method for an electronic device according to the first embodiment of the present disclosure.

[FIG. 5] FIG. 5 is a cross-sectional view showing one step of the manufacturing method for an electronic device according to the first embodiment of the present disclosure.

[FIG. 6] FIG. 6 is a cross-sectional view showing one step of the manufacturing method for an electronic device according to the first embodiment of the present disclosure.

[FIG. 7] FIG. 7 is a cross-sectional view showing one step of the manufacturing method for an electronic device according to the first embodiment of the present disclosure.

[FIG. 8] FIG. 8 is a top view of a cover in the manufacturing method for an electronic device according to the first embodiment of the present disclosure.

[FIG. 9] FIG. 9 is a top view showing a state in which an electronic component is mounted on a wiring board in the manufacturing method for an electronic device according to the first embodiment of the present disclosure.

[FIG. 10] FIG. 10 is a cross-sectional view of an electronic device manufacturing apparatus according to the first embodiment of the present disclosure.

[FIG. 11] FIG. 11 is a cross-sectional view showing one step of a manufacturing method for an electronic device according to a second embodiment of the present disclosure.

[FIG. 12] FIG. 12 is a cross-sectional view showing one step of the manufacturing method for an electronic device according to the second embodiment of the present disclosure.

[FIG. 13] FIG. 13 is a cross-sectional view showing one step of the manufacturing method for an electronic device according to the second embodiment of the present disclosure.

[FIG. 14] FIG. 14 is a cross-sectional view showing one step of the manufacturing method for an electronic device according to the second embodiment of the present disclosure.

[FIG. 15] FIG. 15 is a cross-sectional view showing the electronic device manufacturing apparatus according to the second embodiment of the present disclosure.

### DETAILED DESCRIPTION

Illustrative embodiments of the present disclosure will be described below with reference to the drawings.

As shown in FIG. 1, a manufacturing method for an electronic device according to one embodiment of the present disclosure has Step 11 (i.e., a heating step) and Step 12 (i.e., a bonding step). Each of the steps will be described below with reference to FIG. 1 to FIG. 10.

Step 11 is a step of performing a heat treatment on a mounting structure 8 and a cover 3. Step 11 is a step of heating, in a vacuum, the mounting structure 8 and the cover 3 that is provided at a position where the cover 3 does not face the mounting structure 8 in the top-bottom direction. In Step 11, a bond member that is provided on the cover 3 or the mounting structure 8 is melted.

Step 12 is a step of attaching the cover 3 to the mounting structure 8. Step 12 has a step of moving the cover 3 or the mounting structure 8 so that the cover 3 and the mounting structure 8 face each other and a step of attaching the cover 3 to the mounting structure 8.

Note that, in FIG. 3 to FIG. 7 and FIG. 10, the term “laterally” refers to directions other than the direction immediately above the cover 3, and the term “an upward direction” refers to the forward direction of the hypothetical z-axis.

According to the one embodiment, the mounting structure 8 may sometimes refer to a structure in which an electronic component is mounted on a wiring board as in the example shown in FIG. 9.

In the one embodiment, a vacuum refers to, for example, the range of the low vacuum of 10³ pascals (Pa) to the high vacuum of 10⁻² Pa.

In the one embodiment, the electronic device may be an infrared sensor device or a MEMS device. Examples of the MEMS device include a gyro sensor device, an acceleration sensor device, a vibrator device, and a mirror device.

In the case where the electronic device is an infrared sensor device, the electronic component is an infrared sensor. In the case where the electronic device is an infrared sensor device, the degree of vacuum may be set to be from 1 to 10⁻² Pa (i.e., from a medium vacuum to the high vacuum).

In the case where the electronic device is a gyro sensor device, the electronic component is a gyro sensor element. In the case where the electronic device is an acceleration sensor device, the electronic component is an acceleration sensor element. In the case where the electronic device is a gyro sensor device or an acceleration sensor device, the degree of vacuum may be set to be from 10² Pa to 1 Pa (i.e., a medium vacuum).

In the case where the electronic device is a vibrator device, the electronic component is a vibration element. In the case where the electronic device is a mirror device, the electronic component is a mirror element. In the case where the electronic device is a vibrator device or a mirror device, the degree of vacuum may be set to be from 10³ Pa to 10¹ Pa (i.e., from the low vacuum to a medium vacuum).

As in the example shown in FIG. 10, an electronic device manufacturing apparatus according to a first embodiment of the present disclosure includes a vacuum chamber 9, a support part 5 that supports the cover 3, a moving part 6 that moves the mounting structure 8, and a heating part 7 that heats the mounting structure 8 and the cover 3. The support part 5, the moving part 6, and the heating part 7 are provided in the vacuum chamber 9. The moving part 6 moves the mounting structure 8 so that the cover 3 and the mounting structure 8 face each other from a state where the mounting structure 8 and the cover 3 are displaced from each other in the top-bottom direction.

The vacuum chamber may refer to a casing surrounding the support part 5, the moving part 6, and the heating part 7.

The support part 5 has a recess having a placement area 5a and is a metallic or ceramic plate-like member. The cover 3 is to be placed on the placement area 5a.

The moving part 6 includes a plate member 6a and a jig 6b. The plate member 6a has a placement area 6c for the mounting structure 8. The jig 6b is provided on the plate member 6a. The jig 6b has a through hole. The placement area 6c of the plate member 6a is exposed from this through hole. A space surrounded by this through hole and the placement area 6c may accommodate a part or all of the mounting structure 8. The plate member 6a may have a hole 6d extending downward from the placement area 6c. It is preferable that a plurality of the holes 6d be provided across the entire placement area 6c.

In the manufacturing method for an electronic device according to the one embodiment, as in the examples shown in FIG. 1 to FIG. 10, the cover 3 and the mounting structure 8 face each other by moving the mounting structure 8 so as to be positioned above the cover 3.

A first step is a step of heating the mounting structure 8 and the cover 3 at different temperatures in the interior of the vacuum chamber 9 that is put into a high vacuum state after the mounting structure 8 and the cover 3 are laterally arranged next to each other as in the example shown in FIG. 3. The cover 3 is placed on the placement area 5a. The mounting structure 8 is placed on the placement area 6c.

The interior of the vacuum chamber 9 is kept in a high vacuum state, the degree of vacuum of which is in the range of 10⁻⁵ to 10⁻⁴ Pa, by discharging gas in the vacuum chamber 9 using an evacuation pump 9a. The evacuation pump 9a is a pump connected to the vacuum chamber 9 and for discharging the gas in the vacuum chamber 9 to the outside of the vacuum chamber 9.

The heating treatment may refer to a step of heating the mounting structure 8 and the cover 3 to, for example, in the range of 185° C. to 350° C. using the heating part 7 such as a lamp heater, a heater block, or a heater plate.

In the present embodiment, the mounting structure 8 is heated at a temperature in the range of 280° C. to 350° C. by a first heating body 7a, and the cover 3 is heated at a temperature in the range of 185° C. to 350° C. by a second heating body 7b. The mounting structure 8 and the cover 3 are heated, so that gas adsorbed on the surfaces of the mounting structure 8 and the cover 3 is diffused in the vacuum chamber 9 and discharged by the evacuation pump 9a. The gas flow is indicated by empty arrows in FIG. 10.

The mounting structure 8 and the cover 3 may be individually heated by the heating part 7 such as an infrared lamp heater, heater block, or heater plate. In the case of heating using lamp heaters, each of the lamp heaters is arranged above the mounting structure 8 and above the cover 3, and the mounting structure 8 and the cover 3 are individually and separately heated. This facilitates temperature control, and the mounting structure 8 and the cover 3 can be individually and uniformly heated.

A bond member 4 for bonding a wiring board 2 and the cover 3 together is provided on the cover 3, and the bond member 4 will be in a molten state by being heated by the above-mentioned heating device.

The wiring board 2 is one in which wiring conductors 22 and external terminals are provided on the surface or in the interior of the an insulating base 21, and the wiring board 2 functions as a support for supporting an electronic component 1. The wiring board 2 has a square shape when seen in plan view and may have a recess 24 on which the electronic component 1 is mounted in a center portion thereof. The electronic component 1 may be electrically connected to the wiring conductors 22 via connecting members 10 such as bonding wires. In the wiring board 2, a metal layer 25a may be provided on the top surfaces of sidewalls 25 surrounding the recess 24.

Examples of the insulating base 21 may include ceramics such as an aluminum oxide sintered body (an alumina ceramic), an aluminum nitride sintered body, a mullite sintered body, and a glass ceramics sintered body.

The wiring conductors 22 electrically connect the external terminals and the electronic component 1 together. The external terminals connect the wiring board 2 to an external electric circuit board. The wiring conductors 22 and the external terminals may be made of a metallic material such as tungsten (W), molybdenum (Mo), manganese (Mn), silver (Ag), or copper (Cu).

The cover 3 is to be arranged on the wiring board 2 so as to seal the electronic component 1. The cover 3 has the same size and shape as the wiring board 2 when seen in plan view and may have a square shape when seen in plan view in the one embodiment. The bond member 4 that has a frame shape so as to surround a center portion of the cover 3 may be provided on the outer periphery of the cover 3.

In the case where the electronic component 1 is an infrared sensor element, the cover 3 may be made of a material that transmits infrared radiation, and germanium (Ge), silicon (Si), zinc sulfide (ZnS), or an alloy including these may be used.

In the case where the electronic component 1 is an infrared sensor element, a getter material may be provided on a top surface of the cover 3, which is a surface to be an inner surface of the cover 3 after bonding the mounting structure 8 and the cover 3 together. The getter material may have a frame shape so as to surround a light-receiving portion of the infrared sensor element when seen in plan view. Because of this, after sealing the electronic component 1 with the cover 3, gas molecules that are present in the sealed space is adsorbed by the getter material, and the inside of the sealed space can be put into a further high vacuum state. A chemically active material is used as a material of the getter material. More specifically, a metal mainly composed of titanium (Ti), zirconium (Zr), iron (Fe), and vanadium (V) can be used as a material of the getter material. The getter material may be arranged on the cover 3 by a common deposition method or a sputtering method. The getter material may be in a state ready to adsorb the gas molecules by being simultaneously heated with the cover 3 and being activated in the first step.

In the one embodiment, the bond member 4 is provided on the cover 3. The bond member 4 is a preform of brazing alloy or solder having a frame shape and is arranged so as to surround the center of the cover 3. The bond member 4 may include a metallic material such as a gold-tin brazing alloy, or solder. Although a paste may be used as the bond member 4, a preform that generates an extremely small amount of gas also may be used as the bond member 4.

A second step includes a step of moving the mounting structure 8 by the moving part 6 so as to be positioned above the cover 3 that is supported by the support part 5. Here, the mounting structure 8 is supported by the moving part 6. More specifically, the mounting structure 8 is placed on the placement area 6c.

In the one embodiment, in the second step, the mounting structure 8 is arranged on the moving part 6 so that an opening of the recess 24 is located on the lower side of the mounting structure 8 as in the example shown in FIG. 3. Next, the jig 6b is arranged on the plate member 6a so as to surround the mounting structure 8. Next, the mounting structure 8 and the jig 6b are moved by the plate member 6a in the B direction shown in FIG. 4. The moving part 6 is moved in the B direction and stops so as to position the mounting structure 8 above the cover 3 as in the example shown in FIG. 5. Here, “above the cover 3” refers to a position immediately above the cover 3.

The surface of the moving part 6 on which the mounting structure 8 is to be arranged may be a flat, plate-like member. The moving part 6 may include a metallic material such as stainless steel that generates a small amount of gas. The plurality of holes 6d may be formed in the plate member 6a. Because of this, the gas that is generated from the mounting structure 8 when heating is not likely to accumulate in a space surrounded by the recess 24 and the moving part 6. This is because, as shown in FIG. 10, the gas generated from the mounting structure 8 is diffused in the vacuum chamber 9 via the plurality of holes 6d. Similarly, the holes 6d may be formed in the placement area 5a supporting the cover 3.

As in the examples shown in FIG. 6 and FIG. 7, a third step is a step of suppressing, using the jig 6b, a movement of the mounting structure 8 in a horizontal direction and causing the mounting structure 8 to be dropped onto the cover 3 by moving only the plate member 6a in the horizontal direction. Here, the moving of the plate member 6a in the horizontal direction relates to moving of only the plate member 6a in the C direction in the example shown in FIG. 6.

The movement of the mounting structure 8, which is arranged on the plate member 6a, in the C direction is suppressed by the jig 6b. Therefore, the mounting structure 8 will not move in the C direction even if the plate member 6a is moved in the C direction. Thus, the mounting structure 8 will be dropped onto the cover 3 and will be arranged on the cover 3 as in the example shown in FIG. 7. After the mounting structure 8 is dropped, the bond member 4 becomes solid by being cooled, and the mounting structure 8 and the cover 3 will be bonded together.

The moving part 6 may be moved by controlling driving of a motor with a CPU. More specifically, operations that may be performed by controlling the driving with the CPU include moving the mounting structure 8 up to a position above the cover 3 in the second step, moving only the plate member 6a in the C direction in a state where the jig 6b is stopped in the third step, and the like. The jig 6b may solely be moved in the C direction after the third step by controlling the driving with the CPU.

Since the bond member 4 is pressurized by the weight of the mounting structure 8 after the mounting structure 8 is dropped onto the cover 3, the density of the bond member 4 increases, so that voids in the bond member 4 is reduced in number, and as a result, the bonding strength between the mounting structure 8 and the cover 3 can be enhanced compared to the case where the cover 3 is dropped.

The manufacturing method for an electronic device according to the present embodiment includes, in a vacuum, performing a heating treatment on the mounting structure 8 that includes the wiring board 2 and the electronic component 1 mounted on the wiring board 2 and the cover 3 that is provided at a position where the cover 3 and the mounting structure 8 are displaced from each other in the top-bottom direction, causing the bond member 4 provided on the cover 3 or the mounting structure 8 to melt, and removing gas attached on the surfaces of the cover 3 and the mounting structure 8 from the surfaces of the cover 3 and the mounting structure 8 (i.e., the first step). The manufacturing method for an electronic device according to the present embodiment also includes, in a vacuum, moving the cover 3 or the mounting structure 8 so that the cover 3 and the mounting structure 8 face each other in a state where the bond member 4 is in a molten state (i.e., the second step), and attaching the cover 3 to the mounting structure 8 (i.e., the third step). In the above-described manufacturing method, a portion with a high concentration of gas that is generated from the wiring board 2 and the cover 3 is not likely to be formed. In addition, since the wiring board 2 is moved after heating, the gas around the wiring board 2 can be diffused when moving the wiring board 2, and thus, the concentration of the gas around the wiring board 2 can be reduced. Therefore, the decrease in the degree of vacuum in the sealed space can be reduced by reducing the concentration of the gas that enters the sealed space surrounded by the wiring board 2 and the cover 3 when bonding the wiring board 2 and the cover 3 together.

In the manufacturing method for an electronic device according to the present embodiment, in the above-described configuration, since the mounting structure 8 is moved above the cover 3 so that the cover 3 and the mounting structure 8 face each other, the bond member 4 is pressurized by the weight of the mounting structure 8 after the mounting structure 8 is dropped, and thus, the density of the bond member 4 increases, so that the voids in the bond member 4 is reduced in number, and as a result, the bonding strength between the mounting structure 8 and the cover 3 can be enhanced compared to the case where the cover 3 is dropped.

In the manufacturing method for an electronic device according to the present embodiment, in the above-described configuration, the bond member 4 is provided on the cover 3 in advance, and the bond member 4 is melted by the heating treatment. Therefore, there is no such part as the moving part 6 above the bond member 4, and thus, diffusion of gas generated from the bond member 4 is not blocked. As a result, the gas generated from the bond member 4 can be efficiently diffused.

The electronic device manufacturing apparatus according to the present embodiment includes the vacuum chamber 9, the support part 5 that is provided in the vacuum chamber 9 and supports either one of the mounting structure 8 including the wiring board 2 and the electronic component 1 mounted on the wiring board 2 and the cover 3, the moving part 6 that is provided in the vacuum chamber 9 and moves the cover 3 or the mounting structure 8 so that the cover 3 and the mounting structure 8 face each other from a state where the mounting structure 8 and the cover 3 are displaced from each other in the top-bottom direction, and the heating part 7 that is provided in the vacuum chamber 9 and heats the mounting structure 8 and the cover 3. Such a configuration enables the decrease in the degree of vacuum in the sealed space of the electronic device to be reduced by reducing the concentration of the gas that enters the sealed space surrounded by the wiring board 2 and the cover 3 when bonding the wiring board 2 and the cover 3 together.

In the electronic device manufacturing apparatus according to the present embodiment, in the above-described configuration, the support part 5 has the placement area 5a for the cover 3, and the moving part 6 has the placement area 6c for the mounting structure 8, and thus, the mounting structure 8 can be arranged above the cover 3. The bond member 4 is pressurized by the weight of the mounting structure 8, and thus, the density of the bond member 4 increases, so that the voids in the bond member 4 is reduced in number, and as a result, the bonding strength between the mounting structure 8 and the cover 3 can be enhanced compared to the case where the cover 3 is dropped.

In the electronic device manufacturing apparatus according to the present embodiment, in the above-described configuration, since the moving part 6 has the holes 6d extending from the placement area 6c for the mounting structure 8, the gas generated from the mounting structure 8 is diffused via the holes 6d, and thus, the concentration of gas in the recess of the wiring board 2 of the mounting structure 8 can be reduced.

In the electronic device manufacturing apparatus according to the present embodiment, in the above-described configuration, since the heating part 7 includes the first heating body 7a that heats the mounting structure 8 and the second heating body 7b that heats the cover 3, the mounting structure 8 and the cover 3 can be heated at different temperatures.

### Second Embodiment

Next, a manufacturing method for an electronic device according to a second embodiment of the present disclosure will be described with reference to FIG. 11 to FIG. 15.

In the manufacturing method for an electronic device according to the second embodiment of the present disclosure, a difference from the above-described manufacturing method for an electronic device according to the first embodiment is that, as in the examples shown in FIG. 11 to FIG. 14, the cover 3 is moved so as to be positioned above the mounting structure 8 so that the mounting structure 8 and the cover 3 face each other. In the manufacturing method for an electronic device according to the second embodiment, compared to that of the first embodiment, since the recess 24 of the wiring board 2 is not covered with the moving part 6, the gas generated from the mounting structure 8 is not likely to accumulate in the recess 24, and thus, the concentration of the gas that enters the sealed space can be further reduced.

In this second embodiment, the bond member 4 may be provided on the wiring board 2. More specifically, the bond member 4 may be provided in a frame shape on the top surface of the wiring board 2 so as to surround the recess 24.

As in the example shown in FIG. 15, the cover 3 that has a recess may be used. In this case, the cover 3 may be arranged on the moving part 6 so that an opening of the recess of the cover 3 is located on the side of the moving part 6.

Note that, the present disclosure is not limited to the examples of the above-described embodiments, and various changes can be made. For example, the above-described manufacturing method can be applied when the cover 3 is provided on a multi-cavity wiring board that has a plurality of wiring board regions. The multi-cavity wiring board is to be divided and become the wiring board 2. In this case, the electronic device can be fabricated by dividing the cover 3 and the multi-cavity wiring board together after the cover 3 is provided on the multi-cavity wiring board.

A first member may be heated while arranged on the moving part 6.

The bond member 4 may be in paste form and may be applied and arranged in a frame shape on the cover 3.

The getter material may be provided on the insulating base 21. In this case, metal powder of the getter material that is processed into a paste may be directly sintered on the insulating base 21, or a plate of metal such as cobalt on which the getter material is sintered may be bonded on the insulating base 21 with the brazing alloy or the like.

1. A manufacturing method for an electronic device comprising:
providing a bond member on at least one of a mounting structure comprising a wiring board and an electronic component mounted on the wiring board and a cover;
arranging, in the vacuum, the mounting structure and the cover at positions where the mounting structure and the cover do not face each other when seen in plan view;
heating, in the vacuum, the bond member to a temperature at which the bond member melts or to a higher temperature;
causing, in the vacuum, the cover and the mounting structure to face each other by moving the cover or the mounting structure;
bringing, in the vacuum, the mounting structure and the cover into contact with each other via the bond member that has melted; and
bonding, in the vacuum, the mounting structure and the cover together by solidifying the bond member that has melted.

2. The method according to claim 1,
wherein the moving comprises moving the mounting structure to a position above the cover.

3. The method according to claim 2,
wherein the providing of the bond member comprises providing the bond member on the cover.

4. The method according to claim 1, wherein the arranging comprises:
arranging the mounting structure on a moving member; and
determining a position of the mounting structure by a guide of the moving member.

5. The method according to claim 4, wherein the moving comprises:
moving the moving member and a jig together from a first position where the mounting structure does not face the cover to a second position where the mounting structure faces the cover; and
separating the mounting structure from the moving member by moving the moving member while keeping the jig fixed after the moving member and the jig have reached the second position.

6. An electronic device manufacturing apparatus comprising:
a vacuum chamber;
a support part located in the vacuum chamber, the support part comprising a first placement surface on which a first member is to be placed;
a moving part located in the vacuum chamber, the moving part comprising a second placement surface on which a second member is to be placed, the moving part being movable between a first position where the first placement surface and the second placement surface do not face each other when seen in plan view and a second position where the first placement surface and the second placement surface face each other when seen in plan view; and
a heating part that heats the first member and the second member.

7. The electronic device manufacturing apparatus according to claim 6,
wherein the first member comprises the cover and
wherein the second member comprises the mounting structure comprising a wiring board and an electronic component mounted on the wiring board.

8. The electronic device manufacturing apparatus according to claim 6,
wherein the moving part comprises a through hole in the second placement surface.

9. The electronic device manufacturing apparatus according to claim 6,
wherein the heating part comprises:
a first heating body heating the second member; and
a second heating body heating the first member.

10. The electronic device manufacturing apparatus according to claim 6, further comprising:
a jig provided on the moving part, the jig positioning the second member on the second placement surface by guiding the second member.

11. The electronic device manufacturing apparatus according to claim 10, further comprising:
a mechanism moving the moving part and the jig together when the moving part is moved from the first position to the second position, and
the mechanism returning only the moving part to the first position by separating the moving part from the jig when the moving part is returned to the first position from the second position.

12. An electronic device manufacturing apparatus comprising:
a vacuum chamber; and
a bonding device that is located in the vacuum chamber,
wherein the bonding device comprises:
a support part comprising a first placement surface on which a first member is to be placed;
a moving part comprising a second placement surface on which a second member is to be placed, the moving part movable on the support part;
a guide part located on the moving part, the guide part being capable of moving while fixed to the moving part and being capable of moving separately from the moving part;
a heating part heating the first placement surface and the second placement surface; and
a moving mechanism moving the first placement surface to a position where the first placement surface faces the second placement surface while keeping the guide part fixed on the moving part, the moving mechanism stopping the guide part at the position, and the moving mechanism moving the moving part.

13. The electronic device manufacturing apparatus according to claim 12,
wherein the support part comprises a recess in one surface thereof, and the first placement surface is present in an inner surface of the recess.
